(19) United States
(12) Patent Application Publication
(10) Pub. No.: US 2008/0206911 A1
(43) Pub. Date: Aug. 28, 2008

(54) METHOD OF MANUFACTURING LIQUID CRYSTAL DISPLAY

(75) Inventors: Sun PARK, Suwon-si (KR); Chun-Gi YOU, Hwaseong-si (KR)

Correspondence Address: CANTOR COLBURN, LLP, 20 Church Street, 22nd Floor, Hartford, CT, 06103, US

(73) Assignee: SAMSUNG ELECTRONICS CO., LTD., Suwon-si (KR)

(21) Appl. No.: 11/932,732

(22) Filed: Oct. 31, 2007

(30) Foreign Application Priority Data
Feb. 22, 2007 (KR) 10-2007-0017853

(51) Int. Cl. H01L 21/768

(52) U.S. Cl. 438/30; 257/E21.575

(57) ABSTRACT

A method of manufacturing a liquid crystal display includes depositing a transparent conductive layer on a substrate, depositing a reflective conductive layer on the transparent conductive layer, forming a first photoresist film having a variable thickness on the reflective conductive layer, the variable thickness of the first photoresist film varying according to a position on the reflective conductive layer, first etching the reflective conductive layer and the transparent conductive layer using the first photoresist film as a first etch mask, forming a second photoresist film on the reflective conductive layer by baking the first photoresist film, and second etching the reflective conductive layer using the second photoresist film as a second etch mask.

This application claims priority to Korean Patent Application No. 10-2007-0017853, filed on Feb. 22, 2007, and all the benefits accruing therefrom under 35 U.S.C. §119, the contents of which in its entirety are herein incorporated by reference.

### BACKGROUND OF THE INVENTION

(a) Field of the Invention

The present invention relates to a method of manufacturing a liquid crystal display.

(b) Description of the Related Art

A liquid crystal display (“LCD”) is one of the most widely used flat panel displays. An LCD includes a liquid crystal (“LC”) layer interposed between two panels provided with field-generating electrodes. The LCD displays an image by applying voltages to the field-generating electrodes to generate an electric field in the LC layer. The generated electric field determines orientations of LC molecules in the LC layer to adjust a polarization of incident light, and the light is thereby either blocked by or allowed to pass through a polarizing film, displaying the image.

Depending on a light source of the LCD, the LCD is classified as either a transmissive LCD or a reflective LCD. More specifically, the light source of the transmissive LCD is a backlight in the LCD, and the light source of the reflective LCD is external light. The reflective LCD is usually used in a small or a middle size display device.

Recently, a transflective LCD has been under development. The transflective LCD uses both a backlight and external light, depending on an operating environment and/or settings of the LCD, as light sources. The transflective LCD is usually used in a small or a middle size display device.

Unlike the transmissive LCD or the reflective LCD, the transflective LCD includes pixel electrodes having a double-layered structure, e.g., having transmissive electrodes and reflective electrodes formed on different portions of the pixel electrodes.

Meanwhile, the LCD includes a plurality of thin films such as a gate layer, a data layer, a semiconductor layer and a plurality of pixel electrodes. The thin films are patterned by photolithography using different masks. However, whenever a mask is added, the number of processes, such as exposing, developing, and etching, for example, increases such that manufacturing cost and time increase.

To mitigate increased manufacturing cost and time in the transflective LCD, the pixel electrodes having the double-layered structure are formed by one photolithography and two etching steps using one photo mask having a slit pattern. However, when the pixel electrodes are formed in this manner, the pixel electrodes are undercut due to etching steps such that it is hard to form the pixel electrodes at a desired position.

### BRIEF SUMMARY OF THE INVENTION

According to an exemplary embodiment of the present invention, a method of manufacturing a liquid crystal display includes depositing a transparent conductive layer on a substrate, depositing a reflective conductive layer on the transparent conductive layer, forming a first photoresist film having a variable thickness on the reflective conductive layer, the variable thickness of the first photoresist film varying according to a position on the reflective conductive layer, first etching the reflective conductive layer and the transparent conductive layer using the first photoresist film as a first etch mask, forming a second photoresist film on the reflective conductive layer by baking the first photoresist film, and second etching the reflective conductive layer using the second photoresist film as a second etch mask.

The baking may be performed at about 100 degrees C to about 200 degrees C for about 10 minutes to about 60 minutes, and may include convection heating.

In alterative exemplary embodiments, the baking may be performed at about 100 degrees C to about 270 degrees C for about 10 seconds to about 900 seconds, and may include direct heating.

The second photoresist film may be formed on a lateral side of the transparent conductive layer.

The second photoresist film may be formed on a lateral side of the reflective conductive layer.

The first etching the reflective conductive layer and the transparent conductive layer and the second etching the reflective conductive layer may include wet-etching.

The second photoresist film may be subjected to ashing to reduce a thickness thereof.

The formation of the first photoresist film may include forming a photoresist film arid exposing the photoresist film to light through a mask having a light transmitting area, a translucent area and a light blocking area.

The transparent conductive layer may include one of amorphous indium tin oxide (“a-ITO”) and amorphous indium zinc oxide (“a-IZO”).

The reflective conductive layer may include aluminum.

The reflective conductive layer may include an aluminum-neodymium alloy.

The reflective conductive layer may include a first film including molybdenum and a second film including aluminum.

### BRIEF DESCRIPTION OF THE DRAWINGS

The above and other aspects, features and advantages of the present invention will become more readily apparent by describing in further detail exemplary embodiments thereof with reference to the accompanying drawings, in which:

FIG. 1 is a layout view of a liquid crystal display (“LCD”) according to an exemplary embodiment of the present invention;

FIG. 2 is a partial cross-sectional view taken along lines II-II′, II′-II″ and II″-II′″ of the LCD according to the exemplary embodiment of the present invention in FIG. 1;

FIGS. 3 to 9 are partial cross-sectional views illustrating steps of a method of manufacturing a TFT array panel according to an exemplary embodiment of the present invention of the LCD according to the exemplary embodiment of the present invention in FIGS. 1 and 2;

FIGS. 10A to 10D are partial cross-sectional views illustrating a method of forming pixel electrodes and contact assistants according to an exemplary embodiment of the present invention of the TFT array panel of the LCD according to the exemplary embodiment of the present invention in FIGS. 1 and 2; and

FIGS. 11A to 11D are partial cross-sectional views illustrating a method of forming pixel electrodes and contact assistants according to an alternate exemplary embodiment of the present invention of the TFT array panel of the LCD according to the exemplary embodiment of the present invention in FIGS. 1 and 2.

### DETAILED DESCRIPTION OF THE INVENTION

The invention will now be described more fully hereinafter with reference to the accompanying drawings, in which exemplary embodiments of the invention are shown. The present invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

It will be understood that although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including,” when used in this specification, specify the presence of stated features, regions, integers, steps, operations, elements and/or components, but do not preclude the presence or addition of one or more other features, regions, integers, steps, operations, elements, components and/or groups thereof.

Furthermore, relative terms, such as “lower” or “bottom” and “upper” or “top” may be used herein to describe one element's relationship to other elements as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on the “upper” side of the other elements. The exemplary term “lower” can, therefore, encompass both an orientation of “lower” and “upper,” depending upon the particular orientation of the figure. Similarly, if the device in one of the figures were turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning which is consistent with their meaning in the context of the relevant art and the present disclosure, and will not be interpreted in an idealized or overly formal sense unless expressly so defined herein.

Exemplary embodiments of the present invention are described herein with reference to cross section illustrations which are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes which result, for example, from manufacturing. For example, a region illustrated or described as flat may, typically, have rough and/or nonlinear features. Moreover, sharp angles which are illustrated may be rounded. Thus, the regions illustrated in the figures are schematic in nature and their shapes are not intended to illustrate the precise shape of a region and are not intended to limit the scope of the present invention.

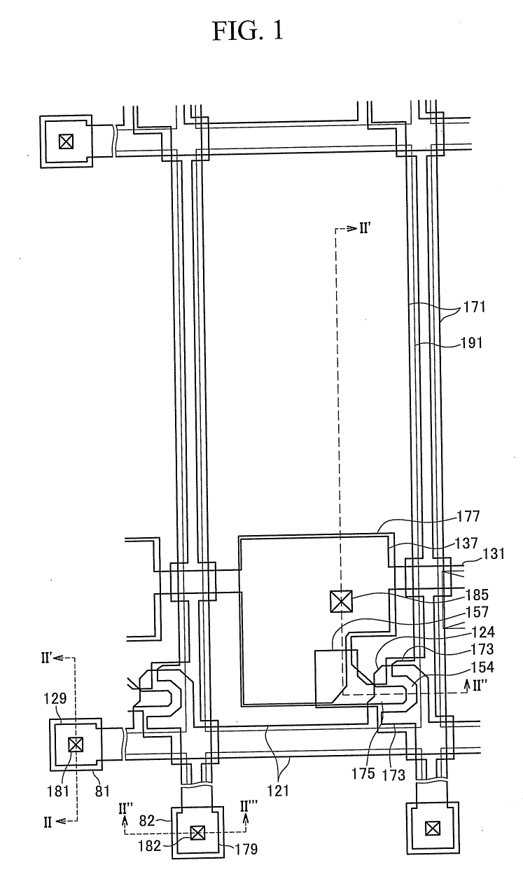

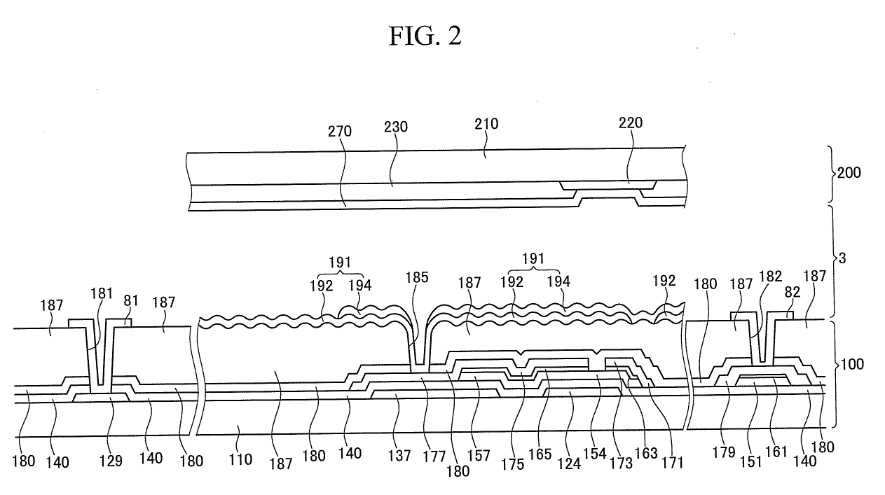

A liquid crystal display (“LCD”) according to an exemplary embodiment of the present invention will now be described in further detail with reference to FIGS. 1 and 2.

FIG. 1 is a layout view of an LCD according to an exemplary embodiment of the present invention, and FIG. 2 is a partial cross-sectional view taken along lines II-Il′, II′-II″ and II″-II′″ of the LCD according to the exemplary embodiment of the present invention in FIG. 1.

An LCD according to an exemplary embodiment of the present invention includes a thin film transistor (“TFT”) array panel 100, a common electrode panel 200, and a liquid crystal (“LC”) layer 3 interposed between the TFT array panel 100 and the common electrode panel 200.

First, the TFT array panel 100 will be described in further detail.

A plurality of gate lines 121 and a plurality of storage electrode lines 131 are formed on an insulating substrate 110 made of a material such as transparent glass or plastic, for example, but is not limited thereto.

The gate lines 121 transmit gate signals and extend in a substantially transverse first direction. Each of the gate lines 121 includes a plurality of gate electrodes 124 projecting downward and an end portion 129 having an area for contact with another layer or a driving circuit (not shown). A gate driving circuit (not shown) for generating the gate signals may be mounted on a flexible printed circuit (“FPC”) film (not shown), which may be attached to the substrate 110, directly mounted on the substrate 110, or integrated with the substrate 110, for example, but is not limited thereto. In alternative exemplary embodiments, the gate lines 121 may extend to be connected to a driving circuit (not shown) which may be integrated with the substrate 110.

The storage electrode lines 131 are supplied with a predetermined voltage and extend in the first direction, e.g., substantially parallel to the gate lines 121. Each of the storage electrode lines 131 is disposed between two associated adjacent gate lines 121 and close to the lower of the two gate lines 121, as shown in FIG. 1. Each of the storage electrode lines 131 includes a storage electrode 137 extending upward and downward. However, the storage electrode lines 131 may have different shapes and arrangements in alternative exemplary embodiments.

A gate insulating layer 140 made of silicon nitride (“SiNx”) or silicon oxide (“SiOx”), for example, but not being limited thereto, is formed on the gate lines 121 and the storage electrode lines 131.

A plurality of semiconductor stripes 151 made of hydrogenated amorphous silicon (“a-Si”) or polysilicon (“p-Si”), for example, but not being limited thereto, are formed on the gate insulating layer 140. Each of the semiconductor stripes 151 extends in a second direction, e.g., substantially perpendicular to the gate lines 121, and includes a plurality of first projections 154 branched out toward the gate electrodes 124 and a plurality of second projections 157 branched out toward the storage electrode 137 from the first projections 154. The semiconductor stripes 151 widen near the gate lines 121 and the storage electrode lines 131 such that the semiconductor stripes 151 cover large areas of the gate lines 121 and the storage electrode lines 131, as shown in FIGS. 1 and 2.

A plurality of ohmic contact stripes 161 and ohmic contact islands 165 are formed on the semiconductor stripes 151. In an exemplary embodiment, the ohmic contact stripes 161 and ohmic contact islands 165 are made of n+ hydrogenated a-Si heavily doped with an N-type impurity such as phosphorous, for example, but are not limited thereto. In alternative exemplary embodiments, the ohmic contact stripes 161 and ohmic contact islands 165 may be made of silicide. Each of the ohmic contact stripes 161 includes a plurality of projections 163, and each of the projections 163 and the ohmic contact islands 165 are located in pairs on the first projections 154 of the semiconductor stripes 151, as shown in FIG. 2.

A plurality of data lines 171 and a plurality of drain electrodes 175 are formed on the ohmic contact stripes 161, the ohmic contact stripe projections 163, the ohmic contact stripe islands 165 and the gate insulating layer 140.

The data lines 171 transmit data signals and extend in the second direction substantially perpendicular to the gate lines 121 to intersect the gate lines 121. Each data line 171 includes a plurality of source electrodes 173 projecting toward the gate electrodes 124, as illustrated in FIG. 1, and an end portion 179 having an area for contact with another layer or a driving circuit (not shown). A data driving circuit (not shown) for generating the data signals may be mounted on an FPC film (not shown), which may be attached to the substrate 110, directly mounted on the substrate 110, or integrated with the substrate 110, for example, but is not limited thereto. In alternative exemplary embodiments, the data lines 171 may extend to be connected to a driving circuit (not shown) which may be integrated with the substrate 110.

The drain electrodes 175 are separated from the data lines 171 and disposed opposite the source electrodes 173 with respect to the gate electrodes 124, as shown in FIGS. 1 and 2. Each of the drain electrodes 175 includes a widened portion 177 and a narrow end portion. The widened portion 177 overlaps the storage electrode 137 of the storage electrode line 131 and the narrow end portion is partly enclosed by a the source electrode 173.

The gate electrode 124, the source electrode 173 and the drain electrode 175 along with a first projection 154 of a semiconductor stripe 151 form a TFT having a channel formed in the projection 154 disposed between the source electrode 173 and the drain electrode 175.

The ohmic contact stripes 161, the ohmic contact stripe projections 163 and the ohmic contact stripe islands 165 are interposed between the underlying semiconductor stripes 151 and the first projections 154 of the semiconductor strips 151 and the overlying data line 171 and drain electrode 175 thereon, and reduce contact resistance therebetween. Although the semiconductor stripes 151 are narrower than the data lines 171 at most places, the width of the semiconductor stripes 151 increases near the gate lines 121 and the storage electrode lines 131, as described above, to smooth the profile of the surface, thereby preventing a disconnection of the data lines 171. However, the semiconductor stripes 151 include some exposed portions which are not covered with the data lines 171 and the drain electrodes 175, such as portions located between the source electrodes 173 and the drain electrodes 175, for example, but not being limited thereto.

A passivation layer 180 is formed on the data lines 171, the drain electrodes 175 and the first projections 154 of the semiconductor stripes 151. The passivation layer 180 may be made of an inorganic or organic insulator, for example, but is not limited thereto.

An organic insulator 187 is formed on the passivation layer 180. The organic insulator 187 may have a dielectric constant of less than about 4.0 and may be photosensitive. Further, the organic insulator 187 may have an embossed surface.

The passivation layer 180, the organic insulator 187, and the gate insulating layer 140 have a plurality of contact holes 181 exposing the end portions 129 of the gate lines 121. The passivation layer 180 and the organic insulator 187 also have a plurality of contact holes 182 and 185 exposing the end portions 179 of the data lines 171 and the drain electrodes 175, respectively.

A plurality of pixel electrodes 191 and a plurality of contact assistants 81 and 82 are formed on the organic insulator 187.

Each of the pixel electrodes 191 is curved along the embossed surface of the organic insulator 187. Each of the pixel electrodes 191 includes a transmissive electrode 192 and a reflective electrode 194 thereon. The transmissive electrode 192 may be made of a transparent conductive material such as amorphous indium tin oxide (“a-ITO”) or amorphous indium zinc oxide (“a-IZO”), and the reflective electrode 194 may be made of an aluminum-containing metal such as aluminum (Al) or an aluminum-neodymium alloy (“AINd”), for example, but are not limited thereto. The reflective electrode 194 may have a double-layered structure including an upper reflective film such as an aluminum-containing metal such as AINd and a lower film made of a molybdenum-containing metal which has good contact characteristics with indium tin oxide (“ITO”) or indium zinc oxide (“IZO”), for example, but is not limited thereto.

The reflective electrode 194 is disposed on portions of the transmissive electrode 192, and the portions of the transmissive electrode 192 on which the reflective electrode 194 is not disposed are thereby exposed.

The pixel electrodes 191 are physically and electrically connected to the drain electrodes 175 through the contact holes 185 such that the pixel electrodes 191 receive data voltages from the drain electrodes 175. The pixel electrodes 191 are supplied with the data voltages to generate an electric field with a common electrode 270 of the opposing common electrode panel 200 which is supplied with a common voltage. The generated electric field determines an orientation of LC molecules (not shown) of the LC layer 3 disposed between the TFT array panel 100 and the common electrode panel 200 to adjust polarization of incident light passing through the LC layer 3. Further, the pixel electrode 191 and the common electrode 270 form a capacitor, referred to as an “LC capacitor,” which stores applied voltages after the TFT is turned off.

A transflective LCD including the TFT array panel 100, the common electrode panel 200 and the LC layer 3 further includes a plurality of transmissive regions and a plurality of reflective regions, defined by the transmissive electrodes 192 and the reflective electrodes 194, respectively In the transmissive regions, light from a backlight unit (not shown) disposed under the TFT array panel 100 passes through the LC layer 3 to display a desired image. In the reflective regions, external light, such as sunlight, for example, but is not limited thereto, which is incident thereon passes through the common electrode panel 200 and through the LC layer 3 to reach the reflective electrodes 194. Then, the external light is reflected by the reflective electrodes 194 and passes through the LC layer 3 again to display a desired image.

A first thickness or cell gap of the LC layer 3 in the transmissive regions is larger than a second thickness or cell gap of the reflective regions. In one exemplary embodiment, the first thickness or cell gap of the transmissive regions may be twice that of the second thickness or cell gap of the reflective regions, but is not limited thereto in alternate exemplary embodiments.

The pixel electrode 191 and the drain electrode 175 connected thereto overlap the storage electrode line 131, as illustrated in FIG. 2. The pixel electrode 191 and the drain electrode 175 electrically connected thereto form an additional capacitor, referred to as a “storage capacitor,” with the storage electrode line 131. The storage capacitor enhances a voltage storing capacity of the LC capacitor.

The contact assistants 81 and 82 are connected to and cover the end portions 129 of the gate lines 121 and the end portions 179 of the data lines 171 through the contact holes 181 and 182, respectively. The contact assistants 81 and 82 protect the end portions 129 and 179 and enhance an adhesion between the end portions 129 of the gate lines 121 and the end portions 179 of the data lines 171 and outside devices (not shown). The contact assistants 81 and 82 may be made on the same layer as the transmissive electrodes 192, for example, but are not limited thereto.

The common electrode panel 200 will now be described in further detail with reference to FIG. 2.

A light blocking member 220 is formed on an insulating substrate 210 made of a material such as transparent glass or plastic, for example, but is not limited thereto. The light blocking member 220, referred to as a black matrix, prevents light leakage. The light blocking member 220 has a plurality of openings (not shown) which face the pixel electrodes 191.

A plurality of color filters 230 are formed on the insulating substrate 210, and are disposed substantially in the plurality of openings of the light blocking member 220. The color filters 230 may extend substantially in the second direction, e.g., substantially perpendicular to the gate lines 121, along the pixel electrodes 191. The color filters 230 may represent the primary colors, e.g., red, green and blue, but are not limited thereto.

According to one exemplary embodiment of the present invention, a first thickness of the color filters 230 depends on a position thereof, and the first thickness of the color filters 230 corresponding to the transmissive regions may be thicker than a second thickness of the color filters 230 corresponding to the reflective regions. In addition, an average thickness of the color filters 230 corresponding to the transmissive regions may be about twice or more than that of the color filters 230 corresponding to the reflective regions, but is not limited thereto in alternative exemplary embodiments.

As described above, each pixel in the transflective LCD includes the transmissive region TA and the reflective region RA. While light passes through the color filter 230 only once in the transmissive region TA, light passes through the color filter 230 twice in the reflective region RA. A difference in the number of times light passes through the color filters 230 may adversely affect color tones of displayed images. However, in the LCD according to one exemplary embodiment of the present invention as described above, an average first thickness of the color filters 230 disposed on the transmissive regions may be twice that of an average second thickness of the color filters 230 disposed on the reflective regions. Therefore, the adverse affect on the color tones due to the different number of times light passes through the color filters 230 is effectively reduced or eliminated.

Referring again to FIG. 2, the common electrode 270 is formed on the color filters 230 and the light blocking member 220. In exemplary embodiment, the common electrode 270 is made of a transparent conductive material such as ITO and IZO, but is not limited thereto in alternative exemplary embodiments.

An overcoat (not shown) may be formed between the color filters 230 and the light blocking member 220 and common electrode 270. The overcoat 250 prevents the color filters 230 from being exposed, provides a flat surface and may be made of an organic insulator, for example, but is not limited thereto.

As described above, the first thickness or the cell gap of the LC layer 3 in the transmissive regions are larger than the second thickness or cell gap of the LC layer 3 in the reflective regions. By forming the overcoat, of which a first thickness thereof disposed on the reflective regions is greater than a second thickness thereof disposed on the transmissive regions, the first and second thicknesses or cell gaps of the LC layer 3 may be adjusted.

Alignment layers (not shown) may be coated on inner surfaces of the TFT array panel 100 and the common electrode panel 200. Further polarizers (not shown) may be provided on outer surfaces of the TFT array panel 100 and the common electrode panel 200.

The LC layer 3 is subjected to vertical alignment or horizontal alignment.

The LCD may further include a plurality of elastic spacers (not shown) which maintain a distance between the TFT array panel 100 and the common electrode panel 200.

The LCD may further include a sealant (not shown) which seals the TFT array panel 100 and the common electrode panel 200 together. The sealant is disposed on the boundary of the common electrode panel 200.

A manufacturing method of the TFT array panel of the transflective LCD according to an exemplary embodiment of the present invention will be now described in further detail with reference to FIGS. 1 to 9.

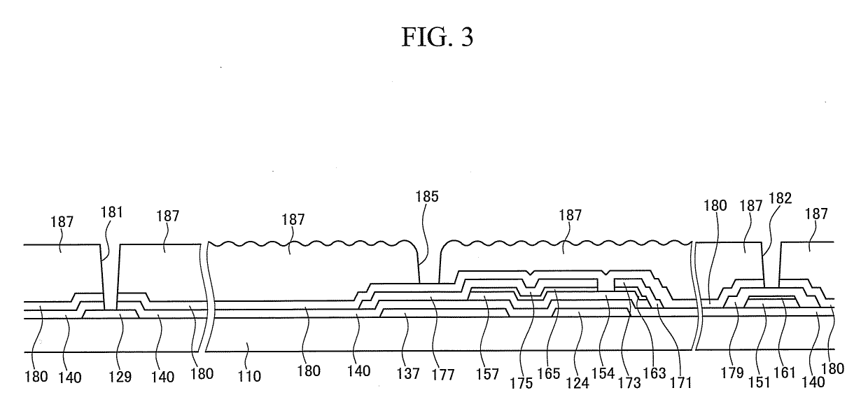

FIGS. 3 to 9 are partial cross-sectional views illustrating steps of a method of manufacturing a TFT array panel according to an exemplary embodiment of the present invention of the LCD according to the exemplary embodiment of the present invention in FIGS. 1 and 2.

As shown in FIGS. 1 and 3, a metal layer is deposited on an insulation substrate 110, and the metal layer is subjected to photolithography and etching to form a plurality of gate lines 121 including a plurality of gate electrodes 124 and end portions 129 and a plurality of storage electrode lines 131 including a plurality of storage electrodes 137.

An insulating layer, an intrinsic a-Si layer in which no impurity is doped, and an extrinsic a-Si layer in which an impurity is doped are then sequentially deposited by chemical vapor deposition (“CVD”). The insulating layer, the intrinsic a-Si layer, and the extrinsic a-Si layer are subjected to photolithography and etching to form a gate insulating layer 140, a plurality of semiconductor stripes 151 made of the intrinsic a-Si layer and including first projections 154 and second projections 157, and a plurality of extrinsic semiconductor stripes including a plurality of projections (not shown).

Next, a metal layer is deposited by a method such as sputtering, for example, but is not limited thereto, and is subjected to photolithography and etching to form a plurality of data lines 171 including source electrodes 173 and end portions 179 and a plurality of drain electrodes 175 having wide end portions 177 and narrow end portions. Sequentially, exposed portions of the extrinsic semiconductor stripes which are not covered with the data lines 171 and the drain electrodes 175 are removed by etching to form a plurality of ohmic contact stripes 161 including projections 163 and a plurality of ohmic contact islands 165 and to expose the underlying semiconductor stripes 151.

Next, a passivation layer 180 made of an inorganic insulating layer is deposited on the gate insulating layer 140, the drain electrodes 175, the data lines 171 and the end portions 179, the projections 163 of the ohmic contact stripes 161, and the first projections 154 of the semiconductor stripes 151. Then an organic insulating layer 187 is deposited on the passivation layer 180. The organic insulting layer 187 and the underlying passivation layer 180 are subjected to photolithography and etching to form a plurality of contact holes 181, 182, and 185.

A portion of the organic insulating layer 187 formed on reflective regions as described in further detail above, is then exposed to light through a slit mask and developed such that the portion of the organic insulating layer 187 formed on the transmissive regions is formed to have an embossed surface, as shown in FIG. 3.

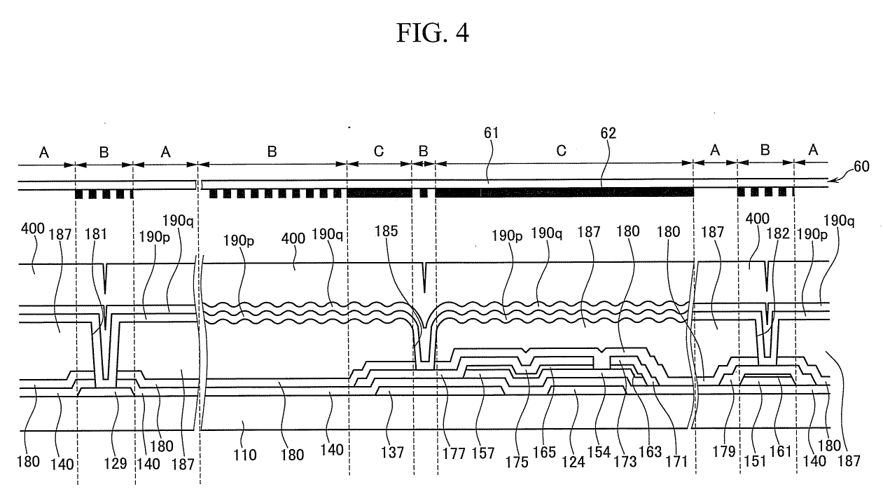

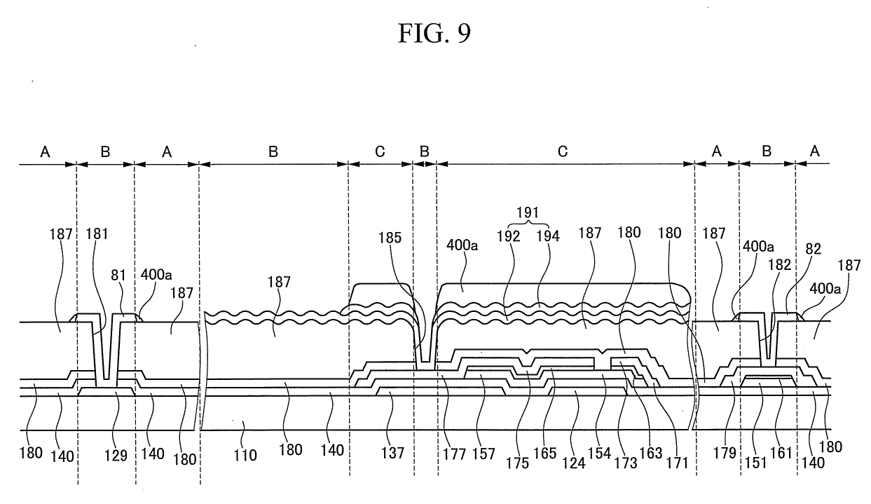

The formation processes of pixel electrodes 191 having transmissive electrodes 192 and reflective electrodes 194 and contact assistants 81 and 82 will be described in further detail with reference to FIGS. 4 and 9.

Referring to FIG. 4, a lower conductive layer 190p made of a transparent conductive material layer such as a-ITO or a-IZO is formed on the organic insulating layer 187, and an upper conductive layer 190q made of a reflective metal such as Al or an aluminum-neodymium alloy is formed on the lower conductive layer 190p. Then, a first photoresist film 400 is coated on the upper conductive layer 190q. The upper conductive layer 190q may include a first film of Molybdenum (Mo) and a second film of Al.

Next, the first photoresist film 400 is exposed to light through a photo mask 60 and developed. An example of the photo mask 60 is shown in the upper portion of FIG. 4.

The photo mask 60 includes a transparent substrate 61 and an opaque member 62 formed on the transparent substrate 61. The photo mask 60 is divided into light transmitting areas A, translucent areas B, and light blocking areas C based on a distribution amount of the opaque member 62 on the substrate 61.

The translucent areas B include the opaque members 62 having a slit pattern, e.g., a width of a predetermined value, for example a smaller width than the resolution of a light exposer used for the photolithography, and disposed with a distance of a predetermined value or less therebetween. In contrast, the light transmitting areas A do not include the opaque members 62, and the light blocking areas C are covered with the opaque member 62.

In alternative exemplary embodiments of the present invention, the translucent areas B may have a lattice pattern, or may be a thin film(s) with intermediate transmittance or intermediate thickness, instead of the slit pattern, for example, but are not limited thereto.

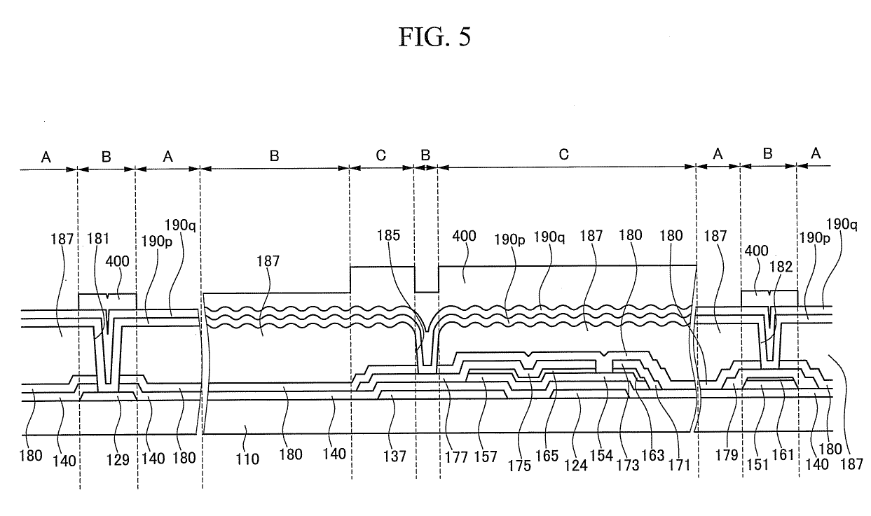

As shown in FIG. 5, the first photoresist film 400 is exposed to light through the photo mask 60 and it is developed such that the developed photoresist film 400 has a position dependent thickness proportional to an amount of received light. For example, a first portion of the first photoresist film 400 facing the light transmitting areas A is removed, a second portion of the first photoresist film 400 facing to the translucent areas B is partially removed, e.g., has a reduced thickness after the exposure to light, and a third portion of the first photoresist film 400 facing the light blocking areas C is not removed, e.g., has substantially the same thickness as before the exposure to light.

A thickness ratio of the second portion of the first photoresist film 400 in the translucent areas B and the third portion of the first photoresist film 400 facing the light blocking areas C is adjusted depending upon the process conditions in the steps described herein. In one exemplary embodiment, a thickness of the second portion of the first photoresist film 400 facing the translucent areas B is less than about half of a thickness of the third portion of the first photoresist film 400 facing the facing the light blocking areas C, but is not limited thereto in alternative exemplary embodiments of the present invention.

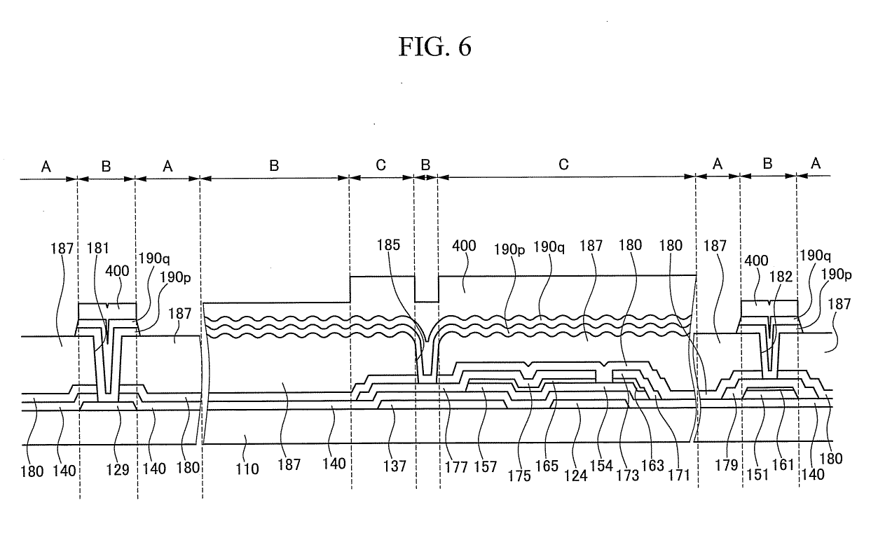

Referring to FIG. 6, the upper conductive layer 190q and the lower conductive layer 190p are sequentially wet-etched using the first photoresist film 400 as an etch mask such that the exposed upper conductive layer 190q and the exposed lower conductive layer 190p are sequentially removed from a portion of the organic insulating layer 187 facing the light transmitting areas A.

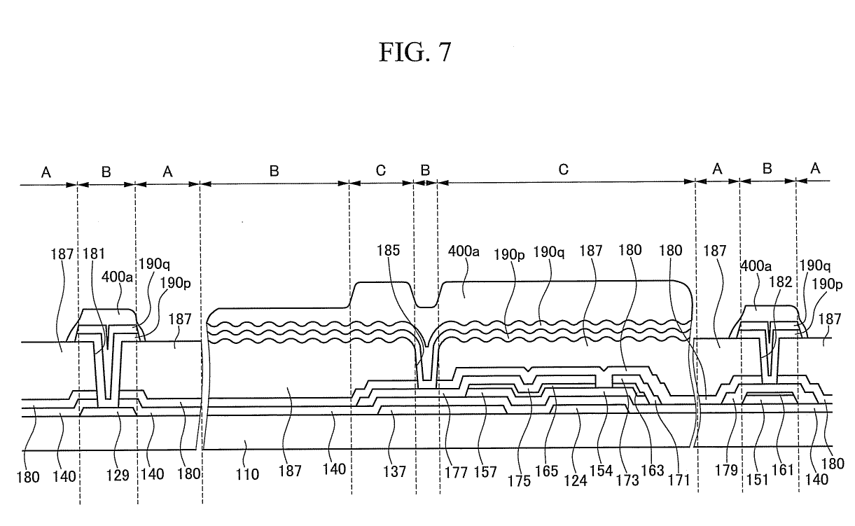

As shown in FIG. 7, the first photoresist film 400 is subjected to baking such that the first photoresist film 400 is reflowed to form a second photoresist film 400a formed on the lateral sides of the upper conductive layer 190q and the lower conductive layer 190p.

The baking process is performed in a convection heating manner or a direct heating manner, for example, but is not limited thereto. Specifically, in the convection heating manner, a convection oven may be used, and in the direct heating manner, a hot plate may be used. When the convection oven is used, the oven heats air, and the heated air indirectly heats the first photoresist film 400 by a convection phenomenon. When the hot plate is used, the substrate 110 including the first photoresist film 400 is heated by the hot plate such that the first photoresist film 400 is directly heated.

In the manufacturing method of the LCD according to one exemplary embodiment of the present invention, when the soft baking of the first photoresist film 400 that is reflowed is performed, the baking may be performed at about 100 degrees C to about 200 degrees C for about 10 minutes to about 60 minutes in the convection heating manner. In the direct heating manner, the heating may be performed at about 100 degrees C to about 270 degrees C for about 10 seconds to about 900 seconds.

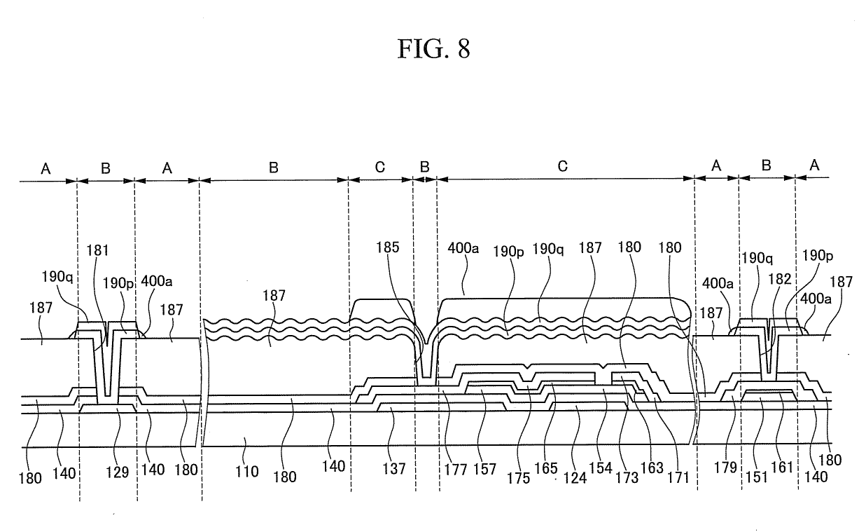

As shown in FIG. 8, the second photoresist film 400a is subjected to ashing, for example, but is not limited thereto, such that remaining portions of the second photoresist film 400a facing the translucent areas B are removed, and the remaining portions of the second photoresist film 400a facing the light blocking areas C have a reduced thickness. Heights of the second photoresist film 400a formed on the lateral sides of the upper conductive layer 190q and the lower conductive layer 190p may be reduced as well, such that the second photoresist film 400a formed on the lateral sides of the upper conductive layer 190q may be removed, and the second photoresist film 400a formed on the lateral sides of the lower conductive layer 190p may be left.

The upper conductive layer 190q is next wet-etched using the remaining portion of the second photoresist film 400a facing the light blocking areas C as a mask, and is removed such that the lower conductive layer 190p facing the translucent areas B is left to form a plurality of pixel electrodes 191 including the transmissive electrodes 192 and the reflective electrodes 194 and contact assistants 81 and 82, as shown in FIG. 9. The remaining portion of the second photoresist film 400a is then removed.

Since the second photoresist film 400a is formed on the lateral sides of the lower conductive layer 190p, an etchant does not permeate the lateral sides of the lower conductive layer 190p during the second wet-etching. Therefore, since the transmissive electrodes 192 made of the lower conductive layer 190p are not removed during the second wet-etching, the reflective electrodes 194 and the transmissive electrodes 192 are formed on the desired positions.

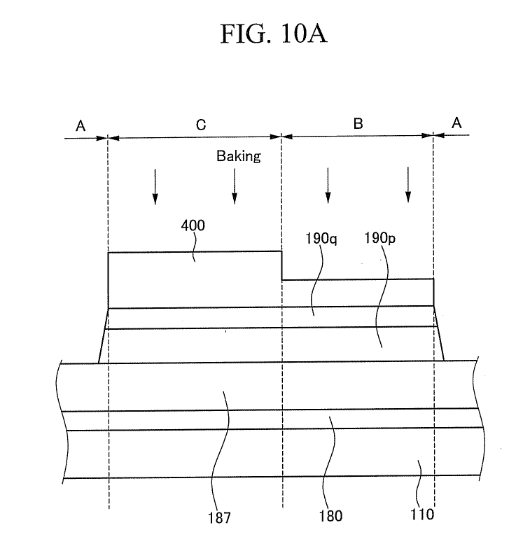

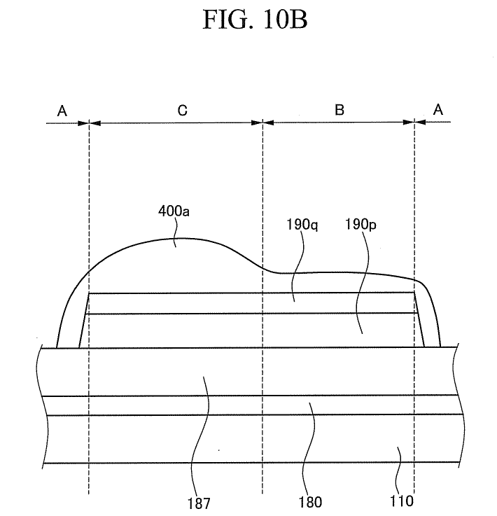

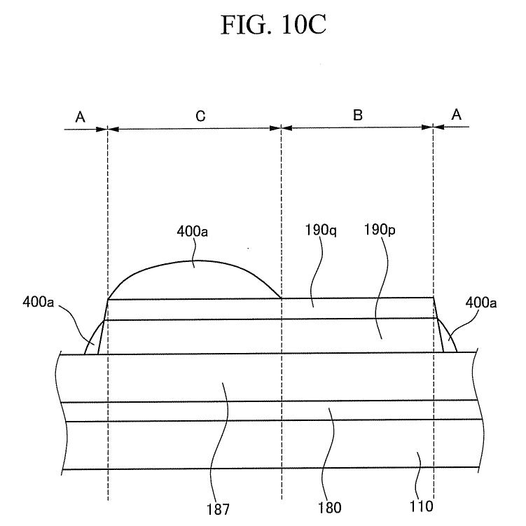

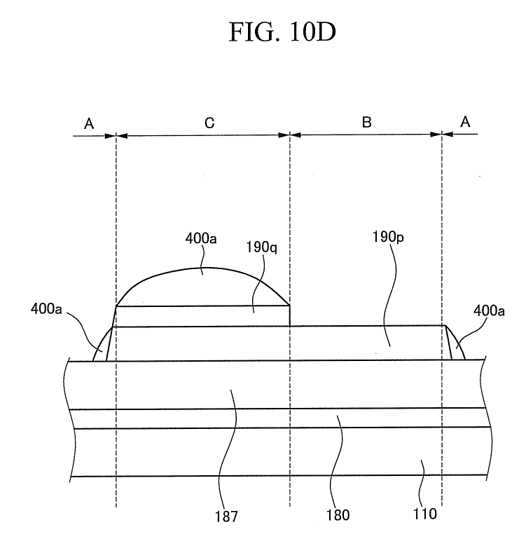

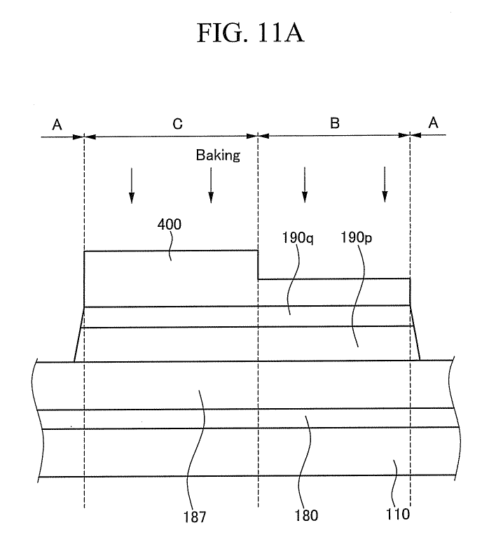

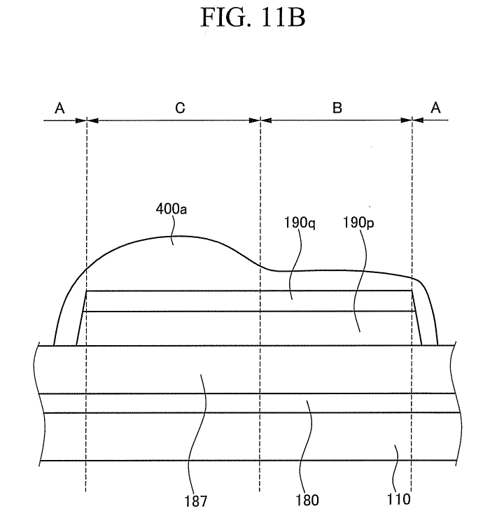

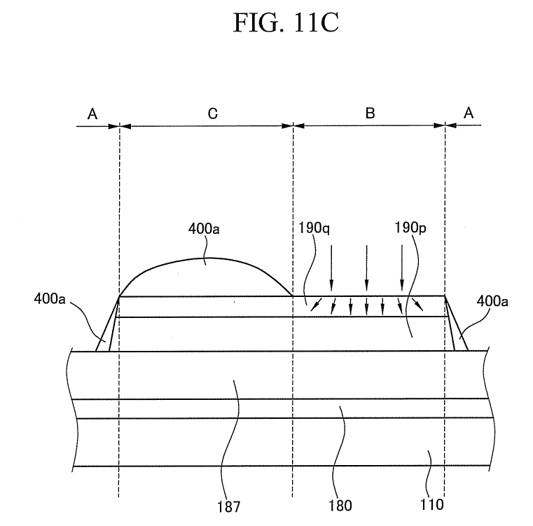

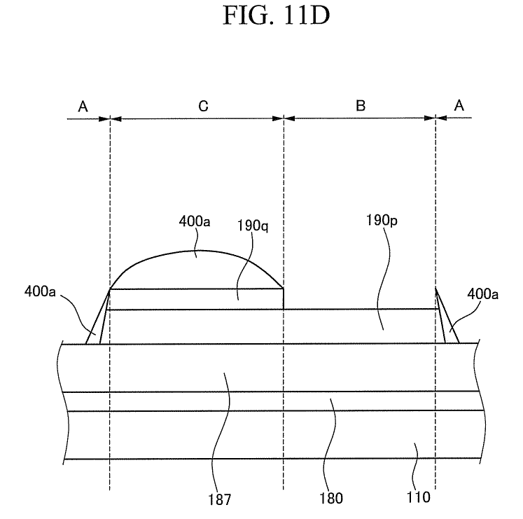

Next, examples of the processes for forming the pixel electrodes 191 and the contact assistants 81 and 82 will be described in further detail with reference to FIGS. 10A to 10D and FIGS. 11A to 11D.

FIGS. 10A to 10D are partial cross-sectional views illustrating a method of forming pixel electrodes and contact assistants according to an exemplary embodiment of the present invention of the TFT array panel of the LCD according to the exemplary embodiment of the present invention in FIGS. 1 and 2, and FIGS. 11A to 11D are partial cross-sectional views illustrating a method of forming pixel electrodes and contact assistants according to an alternate exemplary embodiment of the present invention of the TFT array panel of the LCD according to the exemplary embodiment of the present invention in FIGS. 1 and 2.

Referring to FIGS. 10A to 10D, a method for forming the pixel electrodes 191 and the contact assistants 81 and 82 will be described in further detail. Repetitive descriptions of components already described in reference to FIGS. 1 to 9 have been omitted.

Referring to FIG. 10A, the first photoresist film 400 having position-dependent thicknesses is formed on the lower conductive layer 190p and the upper conductive layer 190q. As described above, the lower conductive layer 190p and the upper conductive layer 190q facing the light transmitting areas A are removed using the first photoresist film 400 as an etch mask. The first photoresist film 400 facing the translucent areas B and the light blocking areas C is baked to form the second photoresist film 400a as shown in FIG. 10B. At this time, the second photoresist film 400a is formed on the lateral sides of the lower conductive layer 190p and the upper conductive layer 190q.

Next, as shown in FIG. 10C, the second photoresist film 400a facing the translucent areas B is removed by ashing the second photoresist film 400a, and the remaining portion of the second photoresist film 400a which faces the light blocking areas C has a reduced thickness. Then, the second photoresist film 400a formed on the lateral sides of the upper conductive layer 190q is removed, while the second photoresist film 400a formed on the lateral sides of the lower conductive layer 190q is left.

As shown in FIG. 10D, the upper conductive layer 190q is wet-etched using the second photoresist film 400a facing the light blocking areas C and the second photoresist film 400a formed on the lateral sides of the lower conductive layer 190p as a mask. At this time, as shown in FIG. 10D, since the second photoresist film 400a formed on the lateral sides of the lower conductive layer 190p is left, the lower conductive layer 190p is not etched.

Referring to FIGS. 11A to 11D, an alternative exemplary embodiment of a method for forming the pixel electrodes 191 and the contact assistants 81 and 82 will be described in further detail.

Referring to FIGS. 11A to 11B, the second photoresist film 400a is formed by baking and reflowing the first photoresist film 400 and then subjecting it to ashing, as described above in reference to FIGS. 10A to 10B. Referring to FIG. 11C, the ashed second photoresist film 400a is formed on the lateral sides of the upper conductive layer 190q as well as the lower conductive layer 190p, in contrast with the method described above in reference to FIG. 10C.

Meanwhile, the upper conductive layer 190q is removed by wet-etching using the second photoresist film 400a as a mask. An etchant permeating through the upper conductive layer 190q wet etches the lower conductive layer 190p as shown by arrows in FIG. 11C. Since the etching is isotropic etching, the etchant permeates equally in a sideward direction and a downward direction. Thereby, although the second photoresist film 400a is formed on the lateral sides of the upper conductive layer 190q, as shown in FIG. 11D, the lateral sides of the upper conductive layer 190q are removed as well.

Accordingly, the pixel electrodes having a double structure of the transmissive electrodes and the reflective electrodes are formed using one mask, and the photoresist film is formed on the lateral sides of the conductive layer as well as the top sides thereof by baking and reflowing. Therefore, an undercut under the transmissive electrodes due to etching twice is effectively prevented or reduced.

The present invention should not be construed as being limited to the exemplary embodiments set forth herein. Rather, these exemplary embodiments are provided so that this disclosure will be thorough and complete and will fully convey the concept of the present invention to those skilled in the art.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A method of manufacturing a liquid crystal display, the method comprising:
depositing a transparent conductive layer on a substrate;
depositing a reflective conductive layer on the transparent conductive layer;
forming a first photoresist film having a variable thickness on the reflective conductive layer, the variable thickness of the first photoresist film varying according to a position on the reflective conductive layer;
first etching the reflective conductive layer and the transparent conductive layer using the first photoresist film as a first etch mask;
forming a second photoresist film on the reflective conductive layer by baking the first photoresist film; and
second etching the reflective conductive layer using the second photoresist film as a second etch mask.

2. The manufacturing method of claim 1, wherein the baking is performed at about 100 degrees Celsius to about 200 degrees Celsius for about 10 minutes to about 60 minutes.

3. The manufacturing method of claim 2, wherein the baking includes convection heating.

4. The manufacturing method of claim 1, wherein the baking is performed at about 100 degrees Celsius to about 270 degrees Celsius for about 10 seconds to about 900 seconds.

5. The manufacturing method of claim 4, wherein the baking includes direct heating.

6. The manufacturing method of claim 1, wherein the second photoresist film is formed on a lateral side of the transparent conductive layer.

7. The manufacturing method of claim 6, wherein the second photoresist film is formed on a lateral side of the reflective conductive layer.

8. The manufacturing method of claim 1, wherein the first etching the reflective conductive layer and the transparent conductive layer, and the second etching the reflective conductive layer include wet-etching.

9. The manufacturing method of claim 1, wherein the second photoresist film is subjected to ashing to reduce a thickness thereof.

10. The manufacturing method of claim 1, wherein the forming the first photoresist film comprises forming a photoresist film and exposing the photoresist film to light through a mask having a light transmitting area, a translucent area and a light blocking area.

11. The manufacturing method of claim 1, wherein the transparent conductive layer comprises one of amorphous indium tin oxide (a-ITO) and amorphous indium zinc oxide (a-IZO).

12. The manufacturing method of claim 1, wherein the reflective conductive layer comprises aluminum.

13. The manufacturing method of claim 12, wherein the reflective conductive layer further comprises an aluminum-neodymium alloy.

14. The manufacturing method of claim 1, wherein the reflective conductive layer comprises a first film comprising molybdenum and a second film comprising aluminum.
